(19) United States
(12) Patent Application Publication
(10) Pub. No.: US 2026/0134938 A1
(43) Pub. Date: May 14, 2026

(54) METHOD TO TEST LDO DRIVING/SINKING IN SOC

(71) Applicant: Taiwan Semiconductor Manufacturing Company, Ltd., Hsinchu (TW)

(72) Inventors: Cheng-Han Lu, New Taipei City (TW); Chia-Fu Lee, Hsinchu City (TW); Yu-Der Chih, Hsinchu City (TW)

(73) Assignee: Taiwan Semiconductor Manufacturing Company, Ltd., Hsinchu (TW)

(21) Appl. No.: 18/947,810

(22) Filed: Nov. 14, 2024

(51) Int. Cl. G11C 29/50; G05F 1/575; G11C 13/00

(52) U.S. Cl. CPC G11C 29/50004; G05F 1/575; G11C 13/0038; G11C 2029/5004; G11C 2029/5006

(57) ABSTRACT

A circuit includes a first voltage provision circuit configured to provide a first output voltage at a first output node. The circuit includes a test circuit coupled to the first voltage provision circuit and configured to test a driving current flowing through the first output node. The test circuit comprises a current mirror. The current mirror comprises a first transistor having a first source/drain terminal coupled to a test pin configured to receive a test current. The current mirror comprises a second transistor having a first source/drain terminal coupled to the first output node.

### BACKGROUND

A low dropout (LDO) regulator is a type of linear voltage regulator that can maintain a steady output voltage, including when the input voltage is relatively higher than the output. LDO regulator can be used in battery-powered devices because of its low power loss and ability to provide stable voltage with relatively minimal overhead.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example block diagram of a memory circuit including a voltage control circuit, in accordance with some embodiments.

FIG. 2 illustrates an example schematic diagram of a circuit including an LDO regulator coupled to a test circuit as part of the memory circuit of FIG. 1, in accordance with some embodiments.

FIG. 3 illustrates an example schematic diagram of a circuit including multiple LDO regulators of FIG. 2 coupled to a test circuit, in accordance with some embodiments.

FIG. 4 illustrates an example schematic diagram of a circuit including a push-pull LDO regulator coupled to a test circuit as part of the memory circuit of FIG. 1, in accordance with some embodiments.

FIG. 5 illustrates an example schematic diagram of a circuit including multiple push-pull LDO regulators of FIG. 4 coupled to a test circuit, in accordance with some embodiments.

FIG. 6 illustrates a flow chart of an example method for operating the test circuit of FIGS. 1-5, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A low-dropout (LDO) regulator is a voltage regulator characterized by a small difference between input voltage and output voltage. LDO regulators have many and various uses in integrated circuit (IC) applications. For example, a memory circuit can include a plural number of LDO regulators, each of which is configured to provide a respective voltage to operate the memory circuit. In the existing technologies, these plural LDO regulators can share a common current source. To accommodate various voltages operating the memory circuit, the common current source can be characterized with the capability to supply a substantially large current. However, there may be variations between the driving capabilities (e.g., maximum driving current) between different LDO regulators, for instance, because of variations in the fabrication processes, types of applications implementing the LDO regulators, or other factors contributing to the performance or capabilities of the LDO regulators. Hence, it may be desired to determine or test the driving capabilities of respective LDO regulators, e.g., to determine the maximum or limit of the driving current from individual LDO regulators or whether the performance of the LDO regulators is within (e.g., satisfy) a predefined specification.

The present disclosure provides various embodiments of a circuit including one or more LDO regulators coupled to a test circuit. The LDO regulator can be configured to provide stable supply or output voltage to a load. For example, the LDO regulator can provide an output voltage for accessing a memory array (e.g., one of a plurality of memory cells) of a memory circuit or device. The consistent or stable voltage from the LDO regulator can allow for a reliable data storage or retrieval operations by the memory array. In various cases, the LDO regulator can help minimize noise and voltage fluctuations, reduce power loss, or enhance data integrity within the memory array, for instance, in low-power applications.

The test circuit can be coupled to the one or more LDO regulators to test the driving current or characteristics of the LDO regulator (or the circuit including the LDO regulator). The test circuit can include at least one current mirror to simulate driving current from the LDO regulator to a respective load (e.g., memory array or non-volatile memory device). The test circuit can incrementally increase the current mirror (e.g., the amplitude or level of the current mirror) and monitor the output voltage from the LDO regulator. As the test circuit increases the current mirror, the output voltage of the LDO regulator may drop when the driving current (mirrored current) reaches a certain level or amplitude. The test circuit can determine the level of driving current causes a drop in the output voltage, e.g., representing the driving capabilities of the LDO regulator, because the output voltage may not be stable at or above a certain level of driving current. In other words, the driving capabilities of the LDO regulator can refer to the maximum driving current supported or capable of being provided by the LDO regulator. Hence, the systems and methods of the technical solution discussed herein can provide a test circuit for testing the driving current of one or more LDO regulators and whether the one or more LDO regulators satisfy the specification (e.g., desired performance or supported capabilities). As a non-limiting example, the LDO regulator(s) coupled to the test circuit can be implemented as part of a memory circuit or a memory device for accessing the memory array or the non-volatile memory device, although the LDO regulator(s) and the test circuit can be implemented in other applications.

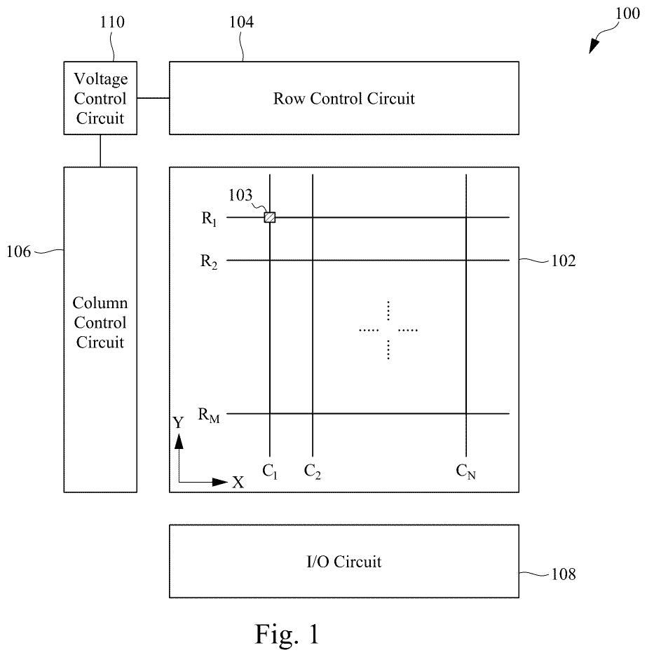

FIG. 1 illustrates a block diagram of an example circuit 100 including a voltage control circuit that can be configured to provide different voltages for operating a memory array, in accordance with various embodiments. For example, the memory circuit 100 can include a memory array 102, a row control circuit (e.g., a driver and/or decoder) 104, a column control circuit (e.g., a driver and/or decoder) 106, an input/output (I/O) circuit 108, and a voltage control circuit 110. Despite not being expressly shown in FIG. 1, all of the components of the memory circuit 100 may be operatively coupled to one another. Although, in the illustrated embodiment of FIG. 1, each component is shown as a separate block for the purpose of clear illustration, in some other embodiments, some or all of the components shown in FIG. 1 may be integrated together.

The memory array 102 is a hardware component that stores data. In various embodiments, the memory array 102 is embodied as a semiconductor memory device. The memory array 102 includes a plurality of memory cells (or otherwise storage units) 103. The memory array 102 includes a number of rows R₁, R₂, R₃ . . . R_{M}, each extending in a first direction (e.g., the X-direction) and a number of columns C₁, C₂, C₃ . . . C_{N}, each extending in a second direction (e.g., the Y-direction). Each of the rows and columns may include one or more conductive (e.g., metal) structures functioning as access lines, e.g., bit lines (BLs), word lines (WLs), and source/select lines (SLs). Each memory cell 103 is arranged in the intersection of a corresponding row and a corresponding column, and can be operated according to voltages or currents through the respective conductive structures of the column and row. For example, each of the rows may include one or more corresponding WLs, and each of the columns may include one or more corresponding BLs and one or more corresponding SLs.

In some embodiments, each memory cell 103 is embodied as a Resistive Random Access Memory (RRAM) cell. However, it should be understood that the memory cell 103 can be implemented as any of various other non-volatile memory cells, while remaining within the scope of the present disclosure. For example, memory cell 103 may include a magnetoresistive random access memory (MRAM) cell, a phase-change random access memory (PCRAM) cell, an efuse memory cell, an anti-fuse memory cell, etc.

In the example of being implemented as an RRAM cell, the memory cell 103 may include a resistor and a transistor coupled to each other in series. The memory cell 103 can be operatively coupled a corresponding set of BL, WL, and SL. The resistor may be formed as a multi-layer stack that includes a top electrode (TE), a capping layer, a variable resistance dielectric (VRD) layer, and a bottom electrode. In some embodiments, the VRD layer may be formed from at least one of the transition metal oxide materials such as, TiOx, NiOx, HfOx, NbOx, CoOx, FeOx, CuOx, VOx, TaOx, WOx, CrOx, and combinations thereof. In some embodiments, the VRD layer may include a high-k dielectric layer. The VRD layer can switch between a high resistance state (HRS) and a low resistance state (LRS), which can correspond to logic 0 and logic 1 of the data bit stored (or programmed) in the memory cell 103.

In general, the TE of the resistor can be coupled to the corresponding BL, the BE of the resistor can be coupled to a first source/drain terminal of the transistor, a gate terminal of the transistor is coupled to the corresponding WL, and a second source/drain terminal of the transistors is coupled to the corresponding SL. To operate the memory cell 103 (which is implemented as an RRAM cell), the transistor is activated (i.e., turned on) by an assertion signal through the WL, and then a voltage with a polarity (e.g., BL is provided with a positive voltage and SL is ground) is applied across the memory cell 103. As such, the higher voltage at BL (and TE) pulls negatively charged oxygen ions from the VRD layer to the capping layer and thus leaves oxygen vacancies within the VRD layer, which allows electron(s) that are present in the BE to travel (hop) from the BE through the VRD and capping layers, and ultimately to the TE. Consequently, a conduction path through the VRD layer is “formed.” Before such a conduction path is formed, the resistor may remain at the HRS. In some embodiments, upon formation of the conduction path, the resistor transitions from the HRS to the LRS, and a relatively higher magnitude of current flows between the BL and the SL.

The row control circuit 104 is a hardware component that can receive a row address of the memory array 102 and assert one or more conductive structures (e.g., a WL) at that row address. The column control circuit 106 is a hardware component that can receive a column address of the memory array 102 and assert one or more conductive structures (e.g., a BL and a SL) at that column address. The I/O circuit 108 is a hardware component that can access (e.g., read, program) each of the memory cells 103 asserted through the row decoder 104 and column decoder 106.

In various embodiments of the present disclosure, the voltage control circuit 110 is a hardware component that can provide a number of suitable voltages to access or otherwise operate the memory array through the row control circuit 104, column control circuit 106, and I/O circuit 108, respectively. For example, the voltage control circuit 110 can include a global LDO regulator configured to provide a standby current, a plural number of charging current sources selectively activated through corresponding switches so as to provide respective levels of a charging current, and/or a number of local LDO regulators configured to provide respective operation voltages for the memory array 102 based on the different charging current levels. The LDO regulator may be a part of at least one other component of the memory circuit 100, configured to provide current or voltage for the operation of the component.

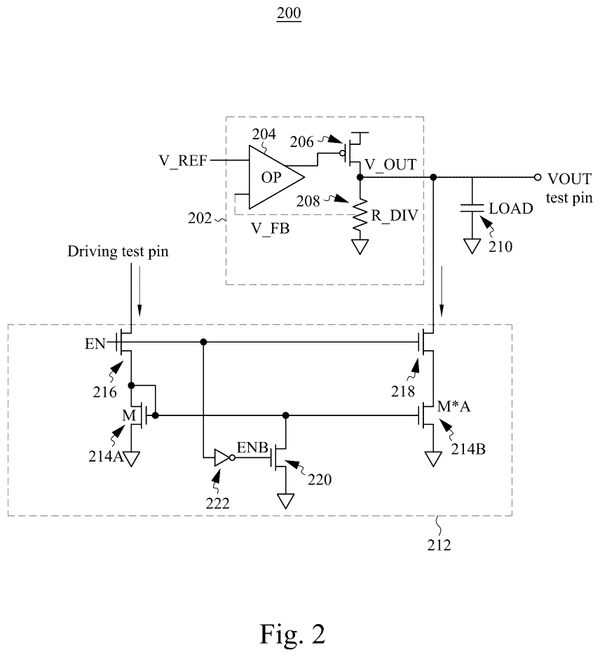

FIG. 2 illustrates an example schematic diagram of a circuit 200 including an LDO regulator 202 coupled to a test circuit 212 as part of the memory circuit 100 of FIG. 1, in accordance with some embodiments. As a non-limiting example, the circuit 200 or components of the circuit 200 (e.g., the LDO regulator 202 and the test circuit 212) can be a part of the voltage control circuit 110, although the circuit 200 can be implemented as a part of other devices or circuits. For instance, the LDO regulator 202 can be a part of the voltage control circuit 110 to provide a driving current or an operation voltage for accessing the memory array 102 or a non-volatile memory device (e.g., the memory circuit 100). The test circuit 212 can be coupled to the LDO regulator 202 to test the driving capabilities of the LDO regulator 202, among other characteristics of the circuit 200, for example.

As shown, the circuit 200 can include the LDO regulator 202 and the test circuit 212. The LDO regulator 202 can sometimes be referred to as a voltage provision circuit. The LDO regulator 202 can be coupled to the test circuit 212 via or at an output node. The output node can represent a node at which an output voltage or a driving current is pushed or provided to a load 210. The output voltage can be measured by a VOUT test pin (e.g., sometimes referred to as a voltage test pin). For instance, the output node of the LDO regulator 202 in FIG. 2 can be a point between the LDO regulator 202 and the load 210 (e.g., at the V_OUT). The test circuit 212 (or at least a portion of the test circuit 212) can be coupled parallel to the load 210, such that during the testing of the LDO regulator 202 (e.g., testing the driving current), the test circuit 212 can simulate a load for the LDO regulator 202 via a current mirror.

The LDO regulator 202 can be utilized to maintain a regulated voltage for a load (e.g., the load 210). The LDO regulator 202 can include various components to maintain V_OUT as the regulated voltage for the load 210. For example, the LDO regulator 202 can include at least an operational amplifier 204, at least one transistor 206, and at least one resistor 208. The LDO regulator 202 can include other components, not limited to the operational amplifier 204, transistor 206, and resistor 208.

The operational amplifier 204 can be utilized as a difference amplifier (e.g., sometimes referred to as an error amplifier), configured to amplify a difference between two voltages. Other types of amplifiers or comparators may be used for the LDO regulator 202, not limited to the operational amplifier 204. The operational amplifier 204 can include two input ports and an output port. The input ports can receive a reference voltage (V_REF) and a feedback voltage (V_FB). The reference voltage may be predefined or pre-configured as an input to the operational amplifier 204. The reference voltage may be from an external device, circuit, or source. In some cases, the reference voltage can represent the desired output voltage from the LDO regulator 202. The feedback voltage can correspond to a voltage across the resistor 208 (e.g., resistor divider (R_DIV)). The feedback voltage can correspond to the actual output voltage at the output node.

The operational amplifier 204 can output a voltage difference or an amplification of the voltage difference between the reference voltage and the feedback voltage. The amplification of the voltage difference can be based on an amplification factor or gain of the operational amplifier 204. The gain can be set by one or more components of the operational amplifier 204, such as at least one of transistor parameters, bias current, resistor sizes, etc. In some cases, the gain can be adjusted by adjusting at least one of, but not limited to, the size of the transistors, bias current, or the resistance or size of the resistors, for example.

The output port of the operational amplifier 204 can be connected or coupled to the gate (e.g., gate terminal or gate electrode) of the transistor 206. The transistor 206 may sometimes be referred to as a pass element. The transistor 206 can be any types of transistor, with a conductive type, such as N-type transistor or P-type transistor. For purposes of providing examples, the transistor 206 can be a P-type transistor configured to allow flow of current when voltage applied at the gate terminal or electrode is lower than the voltage at the source terminal (e.g., voltage from a source), although the LDO regulator 202 can be configured to include an N-type transistor, additionally or alternatively to the P-type transistor. The drain terminal of the transistor 206 can be connected to the resistor 208.

The transistor 206 can be configured to control the flow of current (e.g., driving current) from a source to at least the output node, the load 210, and/or the resistor 208. Controlling the flow of current can include adjusting the level or amount of current flow through the transistor 206. In some cases, the transistor 206 can allow the driving current to at least a portion of the test circuit 212. The transistor 206 can control the current flow according to the voltage level, magnitude, or amplitude applied at the gate terminal of the transistor 206. For example, an increase in the voltage level applied at the gate terminal of the transistor 206 can result in an increase of the current flow through the transistor 206. Conversely, a decrease in the voltage level applied at the gate terminal of the transistor 206 can result in a decrease of the current flow through the transistor 206. The output voltage or the voltage measured across the resistor 208 can be based on the level of driving current, e.g., a relatively higher current flow (or level) can be associated with a relatively higher voltage and a relatively lower current flow can be associated with a relatively lower voltage. The operational amplifier 204 can adjust the gate of the transistor 206 to regulate the output voltage, for instance, by increasing or decreasing the current flow to maintain a desired output voltage level.

The resistor 208 can be referred to as a resistor divider (R_DIV). The resistive divider may be used to sense the output voltage and provide voltage feedback to the operational amplifier 204. The resistance of the resistor 208 can be predefined. The load 210 can be connected between the output node between the transistor 206 and the resistor 208. The load 210 can include be coupled to at least one capacitor to stabilize the output, filtering noise and transients, for example. The load 210 may include or correspond to one or more circuits, devices, or components of the memory circuit 100. For example, the load 210 can include the memory array 102, where the driving current from the LDO regulator 202 can flow through the output node to the memory array 102 (for accessing the memory array 102). The load 210 may be other components of the memory circuit 100, not limited to the memory array 102, where the driving current or the operating voltage from the LDO regulator 202 can be provided to the load 210 to perform a desired operation. In some implementations, the LDO regulator 202 can be a push LDO regulator configured to provide push current via the output node. The LDO regulator 202 may be other types of LDO regulator, not limited to a push LDO regulator.

The test circuit 212 can be connected or coupled to the LDO regulator 202 via the output node. The test circuit 212 can include a plurality of transistors 214A-B, 216, 218, 220. The transistors 214A-B, 216, 218, 220 of the test circuit 212 can have a conductive type, such as a P-type or an N-type transistor. Each of the transistors 214A-B, 216, 218, 220 may have the same conductive type or different conductive types. For purposes of providing examples, the transistors 214A-B, 216, 218, 220 of the test circuit 212 can be N-type transistors, although at least one of the transistors 214A-B, 216, 218, 220 may be a P-type transistor. In some other configurations, the transistors 214A-B, 216, 218, 220 may be P-type transistors. Each of the transistors 214A-B, 216, 218, 220 can include source/drain (S/D) terminals and a gate terminal.

The test circuit 212 can include a current mirror. The current mirror can include the transistors 214A (e.g., M) and 214B (e.g., M*A). The current mirror of the test circuit 212 can be configured to mirror a current (e.g., reference current) flowing from a test pin (e.g., driving test pin) to the driving current flowing from the LDO regulator 202 via/through the output node. Mirroring the current can be performed using at least the transistors 214A-B, where the current flowing through the transistor 214A can be mirrored to the transistor 214B.

For example, a first S/D terminal of the transistor 214A can be coupled to the test pin to receive a test current and a second S/D terminal of the transistor 214A can be coupled to a ground. A first S/D terminal of the transistor 214B can be coupled to the output node and a second S/D terminal of the transistor 214B can be coupled to the ground. The gate terminals of the transistors 214A-B can be connected to each other and the test pin. The voltage applied to the gate terminals can be shared between the transistors 214A-B, which allows the mirroring between the current flowing through the transistor 214A and the driving current flowing through the transistor 214B. For instance, the current supplied by the test pin through the transistor 214A can define the gate voltage for the transistors 214A-B. Because the gate voltage of the transistor 214B is the same as the gate voltage of the transistor 214A, the transistor 214B can pull a proportional amount of current (depending on the transistor sizes) through itself, e.g., the same gate voltage may produce the same current density.

The mirrored current (e.g., driving current) can be scaled by using different transistor sizes between the transistor 214A (e.g., reference transistor) and the transistor 214B. In other words, the current through each of the transistors 214A-B can be proportional to the respective sizes of the transistors 214A-B. For example, if the transistors 214A-B have the same size, the test current (or reference current) from the test pin can be the same or similar to the driving current. For difference transistor sizes, the mirrored current through the transistor 214B can be adjusted to be a multiple of the reference current through the transistor 214A. In some cases, if the transistor 214B is “A” times larger than the transistor 214A, the driving current through the transistor 214B can be around “A” times larger than the reference current. In some other cases, if the transistor 214B is “A” times smaller than the transistor 214A, the driving current through the transistor 214B can be around “A” times smaller than the reference current. In these examples, the “A” can correspond to a multiplier factor that represents, for instance, the ratio of the transistor sizes, e.g., the width or length ratio in metal-oxide-semiconductor field-effect transistors (MOSFETs). In some implementations, the size of the transistor 214B can be based on an expected (or desired) optimal output voltage range, e.g., 7V, 8V, 10V, etc., depending on one or more components of the LDO regulator 202. The implemented transistor size can account for the optimal output voltage of the LDO regulator 202. As such, the mirrored current through the transistor 214B can be scaled according to the multiplier factor. The reference current may be configured or set by an external circuit, such as but not limited to at least one of a current source, a resistor connected to the source of the transistor 214A, or components configured to supply current.

The test circuit 212 can include the transistors 216, 218, 220 configured to control when the test is conducted or terminated. Each of the transistors 216, 218, 220 can include S/D terminals and a gate terminal. As shown, a first S/D terminal of the transistor 216 can be coupled to the test pin and the second S/D terminal of the transistor 216 can be coupled to the first S/D terminal and the gate terminal of the transistor 214A. Further, a first S/D terminal of the transistor 218 can be coupled to the output node (between the transistor 206 and the resistor 208 of the LDO regulator 202 and the second S/D terminal of the transistor 218 can be coupled to the first S/D terminal of the transistor 214B. A first S/D terminal of the transistor 220 can be coupled to the gate terminals of the transistors 214A-B and a second S/D terminal of the transistor 220 can be coupled to ground.

The gate terminals of the transistors 216, 218, 220 can be coupled to an enable port. The gate terminals of at least the transistors 216, 218 can receive an enable signal from the enable port. The enable signal can indicate whether to test the driving current from the LDO regulator 202. The gate terminal of the transistor 220 can receive a logically inverted version of the enable signal via/through an inverter 222. The logically inverted version of the enable signal can sometimes be referred to as an inverted enable signal or enable signal B (ENB). For example, if the enable signal is ‘1’ or high, the inverted enable signal is ‘0’ or low.

To start or initiate the test, the enable signal can be set to ‘1’ to allow the current to flow through the transistors 216, 218. Further, a path to ground via the transistor 220 can be disconnected because of the logically inverted enable signal, e.g., the first S/D terminal and the gate terminal of the transistor 214A can be disconnected from ground. When the first S/D terminal and the gate terminal of the transistor 214A are not connected to ground, the gate voltage at the gate terminal of the transistor 214B can be the same as (or substantially similar to) the gate terminal of the transistor 214A, thereby allowing current mirroring of the reference current through the transistor 214B. To terminate or stop the test, the enable signal can be set to ‘0’ to prevent the flow of current through the transistors 216, 218 and connect the first S/D terminal and the gate terminal of the transistor 214A to ground. By allowing the path to ground via the transistor 220, the gate terminal of the transistor 214B can be grounded (e.g., 0V), disabling the flow of current via the transistor 214B and preventing or terminating current mirroring. It should be noted that the test circuit 212 may include additional components or fewer components to those described herein.

At least a portion of the test circuit 212 can simulate the load 210 or the amount of load connected to the LDO regulator 202. In various configurations, the enable signal can be set to a high state (e.g., ‘1’) to start testing the driving current. In some configurations, the enable signal may be set to a low state (e.g., ‘0’) to end or stop the test. To test the driving current or the capability of the LDO regulator 202, the reference current can be increased incrementally or gradually over time during the test. Because the reference current is mirrored to the driving current, the driving current also increase when the reference current increases. Increasing the reference current and the driving current can simulate an increase in the load 210 connected to the LDO regulator 202, e.g., testing whether the performance of the LDO regulator 202 satisfy the specification.

While increasing the reference current (and thereby the driving current), the VOUT test pin can (continuously or periodically) monitor the output voltage at the output node. At a certain level (e.g., magnitude or amplitude) of the driving current, the VOUT test pin may detect a drop in the output voltage at the output node. This drop in the output voltage during the increase of the driving current can be an indicator that of a maximum driving current by the LDO regulator 202. It should be noted that the systems and methods of the present disclosure can include a device or a system (not shown) configured to provide the reference current and obtain output voltage information from the circuit 200, such as the voltage control circuit 110, at least one component of the voltage control circuit 110, or an external circuit or device coupled to the one or more components of the circuit 200. As such, in various implementations, the circuit 200 can be referred to herein as the device, system, or component that identifies the output voltage drops, captures the driving current at or around an instance when the output voltage dropped/decreased or fluctuated, etc.

The circuit 200 can be in communication with one or more external devices. The circuit 200 can provide information related to the test to the authorized external device, such as to present the test data or test result. For example, the circuit 200 can identify the whether the output voltage drops. In response to the drop in the output voltage, the circuit 200 may provide an indication of the output voltage drop to the external device (e.g., informing the administrator or the user). In some cases, the circuit 200 can provide the level of the driving current (e.g., maximum driving current) that causes the drop in the output voltage to the external device. In some other cases, the circuit 200 may provide an indication indicating whether the LDO regulator 202 satisfy the specification (e.g., whether the (maximum) driving current is at or above a desired threshold when the output voltage drops). The circuit 200 may provide other indications to the external device, not limited to those discussed herein.

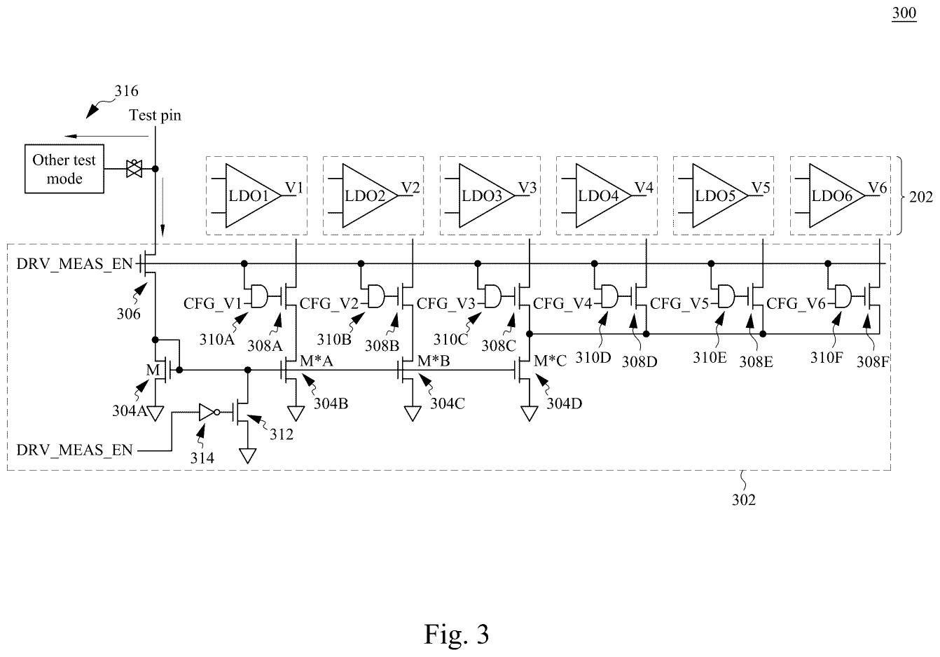

FIG. 3 illustrates an example schematic diagram of a circuit 300 including multiple LDO regulators 202 of FIG. 2 coupled to a test circuit 302, in accordance with some embodiments. The circuit 300 can include one or more components, devices, or circuits similar to those in the circuit 200. The circuit 300 can include one or more components, devices, or circuits additional or alternative to those in the circuit 200. The circuit 300 can include one or more features or perform one or more operations as described in conjunction with at least FIG. 2. For example, the circuit 300 can include a plurality of LDO regulators 202. Each of the LDO regulators 202 can include one or more components described in conjunction with at least FIG. 2. Each of the LDO regulators 202 can be configured to provide a regulated voltage for accessing at least a respective portion of the memory array 102. In another example, the circuit 300 can include the test circuit 302, including one or more components similar to the test circuit 212. As described in conjunction with at least FIG. 2, the test circuit 302 can be configured to test the driving current or the characteristics of each LDO regulator 202. The test circuit 302 can include additional or alternative components compared to the test circuit 212, for example. The LDO regulators 202 may be a part of the voltage control circuit 110. The circuit 300 can be implemented as part of various IC applications.

As shown, the circuit 300 can include the LDO regulators 202, including LDO1-LDO6. The circuit 300 may include more or a smaller number of LDO regulators 202. Individual LDO regulators 202 can be rated to support a certain level of driving current according to the specification. Individual LDO regulators 202 can be configured to output a predefined output voltage, for instance, according to the reference voltage received as input to the operational amplifier of the respective LDO regulator 202. For instance, LDO1-LDO6 can be configured to provide output voltages V1-V6, respectively, at the respective output nodes associated with the LDO1-LDO6. The output voltages V1-V6 may be different from each other. Individual LDO regulators 202 can be connected or electrically coupled to respective parts/portions of the test circuit 302, where the test can be initiated for each LDO regulators 202. For example, individual LDO regulators 202 can be connected to transistors 308A-F, respectively. Although not shown, individual LDO regulators 202 may be connected to a load (e.g., load 210), multiple loads, or the memory array 102, among others.

The test circuit 302 can include a plurality of transistors 304A-D, 306, 308A-F, 312, configured to test the driving current one or more LDO regulators 202 using a single current source (e.g., current from the test pin). It should be noted that the test circuit 302 can test the LDO regulators 202 using current from other sources. The transistors 304A-D, 306, 308A-F, 312 can include a conductive type, such as N-type or P-type transistors. For purposes of providing examples, the transistors can be N-type transistors, although other types of transistors can be utilized for the test circuit 302.

The test circuit 302 can include a current mirror, comprising transistors 304A-D (e.g., sometimes referred to as transistor(s) 304). The transistors 304 can be described in conjunction with the transistors 214A-B of FIG. 2. For example, the current mirror can mirror a reference current flowing through the transistor 304A (e.g., reference transistor) to one of the transistors 304B-D, depending on which of the LDO regulators 202 is to be tested. The current through the transistors 304B-D can be referred to as the driving current of the respective LDO regulators 202 or mirrored current. Each of the transistors 304 can include S/D terminals and a gate terminal. As shown, the first S/D terminal of the transistor 304A can be connected to the test pin (via the transistor 306) and the second S/D terminal of the transistor 304A can be grounded. The first S/D terminal of the transistor 304A can be coupled to the gate terminal of the transistor 304A, such that the reference current flow through the first S/D terminal can be used to generate a gate voltage at the gate terminal, e.g., a higher reference current produce a higher gate voltage.

Individual transistors 304B-D can include a respective first S/D terminal coupled to an output node of one or more respective LDO regulators 202 (via the respective transistors 308A-F). The second S/D terminals of the transistors 304B-D can be grounded. The gate terminals of the transistors 304B-D can be coupled to the gate terminal of the transistor 304A, such that the gate voltage is shared between the transistors 304. By sharing the gate voltage, the reference current through the transistor 304A can be proportional or mirrored to the driving current through the transistors 304B-D.

The mirrored current can be proportional to the size of the transistors 304, such as described in conjunction with at least FIG. 2. In various implementations, the size of the transistors 304 can be predefined or selected according to the driving range (e.g., expected or desired driving current) for individual LDO regulators 202. For example, depending on the sizes of the transistors 304B-D relative to the size of the transistor 304A, the mirrored current of a respective one of the transistor 304B-D can be a multiple of the reference current according to the ratio between the corresponding one of the transistor 304B-D and the transistor 304A. If the transistor 304B is twice as large as the transistor 304A, the mirrored current of the transistor 304B can be two times greater or larger than the reference current. If the transistor 304C is three times larger than the transistor 304A, the mirrored current of the transistor 304C can be three times larger than the reference current. If the transistor 304D is 2.5 times larger than the transistor 304A, the mirrored current of the transistor 304D can be 2.5 times larger than the reference current, etc. In some implementations, at least one of the transistors 304B-D may be smaller than the transistor 304A. In such cases, the mirrored current of the corresponding one of the transistors 304B-D can be smaller than the reference current based on the sizes between the transistor 304A and the corresponding one of the transistors 304B-D.

The test circuit 302 can include transistors 306, 308A-E, 312 to start or stop the testing procedures/operations of at least one of the LDO regulators 202. Each of the transistors 306, 308A-E can include S/D terminals and a gate terminal. The first S/D terminal of the transistor 306 can be coupled to at least the test pin and the second S/D terminal of the transistor 306 can be coupled to the first S/D terminal of the transistor 304A. The first S/D terminal of the transistor 306 may share a connection with other circuits (e.g., other test circuits) for other test modes (e.g., 316), e.g., the other test modes 316 may receive the reference current from the same test pin (e.g., current source). The gate terminal of the transistor 306 can be connected to an enable signal port configured to receive an enable signal indicative of whether to start or stop testing the driving current of at least one of the LDO regulators 202.

The transistors 308A-E can sometimes be referred to as transistor(s) 308. The transistors 308 can include respective first S/D terminals in connection with respective output nodes of the respective LDO regulators 202. The transistors 308 can include respective second S/D terminals in connection with the respective first S/D terminals of one or more of the transistors 304B-D. For example, the second S/D terminal of the transistor 308A can be connected to the first S/D terminal of the transistor 304B, the second S/D terminal of the transistor 308B can be connected to the first S/D terminal of the transistor 304C, and the second S/D terminals of the transistor 308C-F can be connected to the first S/D terminal of the transistor 304D.

The transistors 308 can include respective gate terminals connected to the enable signal port and the gate terminal of the transistor 306 via respective logic gates 310A-F (e.g., AND gates 310A-F). The logic gates 310A-F can sometimes be referred to as logic gate(s) 310. The logic gates 310 can be utilized to control individual transistors 308, e.g., allow or prevent current flow through individual transistors 308 for testing the driving current of at least one corresponding LDO regulator 202. For example, the enable signal can be provided to the gate terminal of the transistor 306 and an input of each logic gate 310. If the enable signal is in a high state or ‘1’, the transistor 306 can allow the reference current to flow. The second input of the logic gates 310 can be set to a low state (e.g., ‘0’) as a default state. To allow current through any of the transistors 308, the second input of the logic gate 310 associated with the transistor 308 can be set to a high state or ‘1’. For instance, when the enable signal is ‘1’, the current from individual LDO regulators 202 can flow through the respective transistors 308 by setting configuration voltages (CFG_V1-V6) to ‘1’ (or a high state), respectively. With the AND gate, the high enable signal and configuration voltage can result in a logic output of ‘1’, thereby applying a gate voltage to the respective transistor 308. The configuration voltage can be provided from the external device or circuit. For instance, the configuration voltage can switch between the high state and the low state sequentially for each of the transistors 308 to sequentially test the corresponding LDO regulators 202.

The transistor 312 can receive an inverse enable signal via the inverter 314. The transistor 312 can operate similar to the transistor 220, as described in conjunction with at least FIG. 2. The inverter 314 can operate similar to the inverter 222 described in conjunction with at least FIG. 2, for example. The transistor 312 can coupled the gate terminals of the transistors 304A-D to ground when the enable signal is in the high state, e.g., the inverted enable signal is in the low state. The transistor 312 can prevent the gate terminals of the transistors 304A-D from being grounded when the enable signal is in the low state, e.g., the inverted enable signal is in the high state.

The operations for testing the driving current or the LDO regulators 202 can be described in conjunction with at least FIG. 2. For example, the transistor 306 can receive a high enable signal to start the testing. To test the driving current of LDO1 (e.g., a first voltage provision circuit), the configuration voltage of the logic gate 310A can be set to a high state, such that the transistor 308A can allow the flow of the driving current from LDO1 through the transistor 304B. The driving current through the transistor 304B can mirror the reference current through the transistor 304A. The test circuit 302 can incrementally increase the reference current (over time), which in turn increases the driving current from the LDO1. The output voltage at the output node of the LDO1 can be monitored during the test to identify whether the output voltage drops. In response to identifying a drop in the output voltage, the test circuit 302 can determine the driving current level from the LDO1 that causes the output voltage drop.

The determined driving current level can represent the maximum driving current for the LDO1, which can be compared to a driving current threshold to determine whether the LDO1 satisfy the specification. The threshold associated with the LDO1 may be different from thresholds associated with other LDO regulators 202. In some cases, the threshold can be associated with multiple LDO regulators 202. For instance, the specification of one LDO regulator 202 may be the same as or different from other LDO regulators 202, thereby either sharing the same driving current threshold or assigning individual driving current thresholds for one or more LDO regulators 202, respectively.

The testing of the LDO1 can be perform similarly for one or more other LDO regulators 202, such as at least one of but not limited to LDO2-6. For instance, to start testing LDO2, the configuration voltage of the logic gate 310A can be set to a low state and the configuration voltage of the logic gate 310B can be set to a high state, thereby allowing current flow through the transistor 308B. Similar operations described in conjunction with LDO1 can be performed to test the driving current of LDO2, among others.

In some implementations, depending on the expected or desired driving current supported by individual LDO regulators 202, different transistor sizes for the current mirror can be configured in association with the individual LDO regulators 202. The higher the driving current that is expected to be supported by the LDO regulator 202, the greater the size of at least one of the transistors 304B-D associated with the LDO regulator 202, for instance, for a larger multiplier of the reference current. The lower the driving current is expected to be supported by the LDO regulator 202, the smaller the size of at least one of the transistors 304B-D associated with the LDO regulator 202.

In some arrangements, if multiple LDO regulators 202 are expected to support around the same minimum driving current, the multiple LDO regulators 202 can be associated with the same (or similar) transistor for current mirror, e.g., transistors of a similar size or connected to the same transistor. For example, as shown in FIG. 3, LDO3-6 can be associated with or connected to the transistor 304D. In this case, the LDO3-6 may be associated with the same specification, hence sharing the same transistor 304D such that the mirrored current is similar in magnitude or amplitude during the testing. The LDO3-6 can be tested individually.

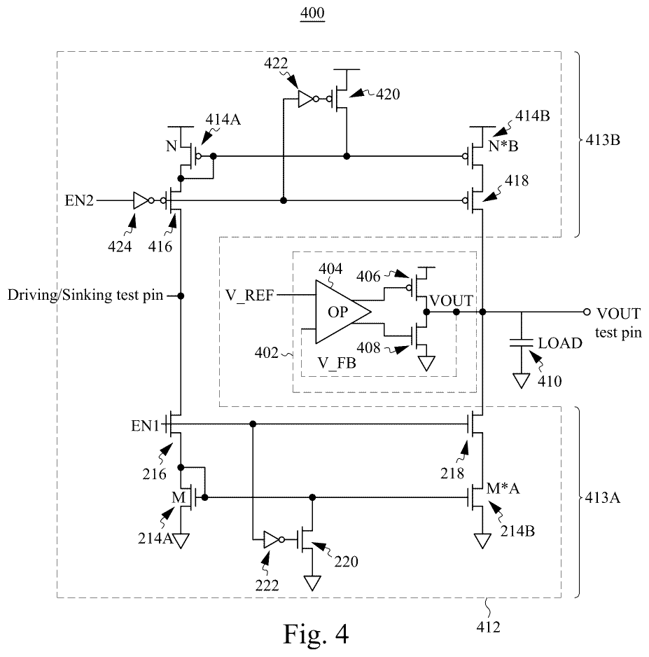

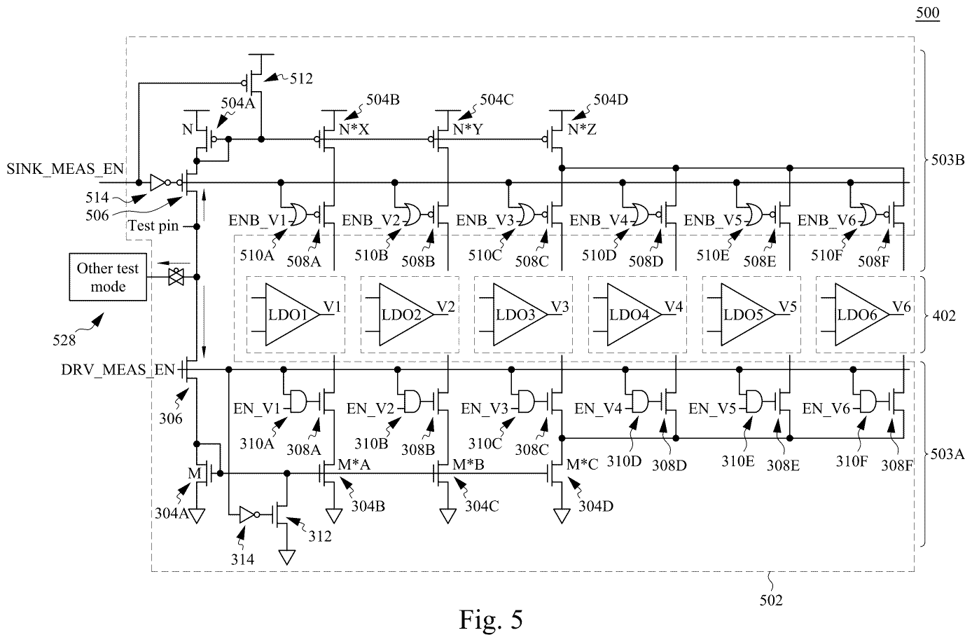

The circuit 300 can include other test modes 316, such as for testing other LDO regulators in addition to the LDO regulators 202. The other test modes 316 may include at least one other test circuit, for example. In some cases, the other test modes 316 may refer to at least one of circuits 400, 500 as described in conjunction with at least one of FIGS. 4-5, among others. The other test modes 316 can include other circuits, such as for testing additional or alternative LDO regulators, sharing the same test pin providing the reference current.

FIG. 4 illustrates an example schematic diagram of a circuit 400 including a push-pull LDO regulator 402 coupled to a test circuit 412 as part of the memory circuit 100 of FIG. 1, in accordance with some embodiments. The circuit 400 can include one or more components similar to at least one of but not limited to circuits 200, 300 described in conjunction with FIGS. 2-3. The circuit 400 can include additional or alternative components to circuits 200, 300. The circuit 400 can include one or more features or perform one or more operations similar to or different from at least one of but not limited to circuits 200, 300, described in conjunction with FIGS. 2-3. For example, the circuit 400 can include an LDO regulator 402 and a test circuit 412. The LDO regulator 402 can be configured to provide an output voltage, for instance, for accessing at least a portion of the memory array 102 of the memory circuit 100. The LDO regulator 402 may include one or more components similar to (or different from) the LDO regulator(s) 202. The test circuit 412 can be configured to test the LDO regulator 402, the driving current of the LDO regulator 402, or the characteristics of the circuit 400, for example. The test circuit 412 can include one or more components similar to (or different from) at least one of the test circuits 212, 302, as described in conjunction with FIGS. 2-3, among others. In this case, the test circuit 412 can be configured to test the pull current (e.g., pull driving current) and the push current (e.g., push driving current) from the LDO regulator 402 (e.g., sometimes referred to as a push-pull LDO regulator 402), e.g., testing the LDO regulator 402 sinking ability. It should be noted that the circuit 400 and/or the components of the circuit 400 can include additional or alternative components, not limited to those discussed herein.

As shown, the LDO regulator 402 can include an operational amplifier 404 and transistors 406, 408. The operational amplifier 404 can be similar to the operational amplifier 204 for controlling the gate of the transistor 408 according to the reference voltage (V_REF) and the feedback voltage (V_FB) (e.g., output voltage). For example, based on the difference between the reference voltage and the feedback voltage, the operational amplifier 404 can output (e.g., a first output) an amplification of the difference to the gate terminal of the transistor 408. In this case, the operational amplifier 404 can output (e.g., a second output) an inverse version of the amplified difference to the transistor 406. As shown, the transistors 406, 408 can have different conductive type. In this case, the transistor 406 can be a P-type transistor and the transistor 408 can be an N-type transistor. In such cases, the gate voltage applied to the transistor 408 can produce the same current density as the inverse gate voltage applied to the transistor 406. The output node can be between the transistors 406, 408. A load 410 can be coupled connected to the output node. The load 410 can be similar to the load 210, for example.

The test circuit 412 can be coupled to the output node to test the driving current of the LDO regulator 402. In this case, the test circuit 412 can test both the push driving current and the pull driving current. The push current and pull current can refer to the direction of the driving current. For example, the push current can refer to the sourcing current from a component to the load, e.g., from the LDO regulator 402 to the load 410 (or to the test circuit 412 simulating the load 410). The pull current can refer to the sinking current from the load 410 to the component, e.g., from the load 410 (or the test circuit 412) to the LDO regulator 402, and subsequently to ground. For purposes of providing examples, portion 413A of the test circuit 412 can be configured to test the push driving current from the LDO regulator 402 and portion 413B of the test circuit 412 can be configured to test the pull driving current to the LDO regulator 402, or vice versa in some configurations.

The portion 413A of the test circuit 412 can include components similar to at least the test circuit 212 of FIG. 2, for example. The portion 413B of the test circuit 412 can include similar layout as the portion 413A, including transistors 414A-B, 416, 418, 420 having a conductive type different (or opposite) from the conductive type of the transistors 214A-B, 216, 218, 220. The transistors 414A-B, 416, 418, 420 having the different conductive type can allow the test circuit 412 to test the driving current pulled to the LDO regulator 402, for example. For purposes of providing examples, the transistors 414A-B, 416, 418, 420 can be P-type transistors and the transistors 214A-B, 216, 218, 220 can be N-type transistors, although the conductive type of the transistors may be swapped between the portions 413A-B.

The transistors 414A-B of the test circuit 412 can be a part of another current mirror (e.g., a second current mirror) different from a first current mirror associated with the transistors 214A-B. The transistors 414A-B can have a conductive type different from the transistors 214A-B. Each of the transistors 414A-B, 416, 418, 420 can include S/D terminals and a gate terminal. As shown, the gate terminal and a first S/D terminal of the transistor 414A can be coupled to each other and to the test pin. The second S/D terminal of the transistor 414A can be coupled to a source, e.g., for the pull current. The transistor 414B can include a first S/D terminal connected to the output node (via the transistor 418), a second S/D terminal connected to the source, and a gate terminal connected to the gate terminal of the transistor 414A. The transistors 414A-B can perform current mirroring similar to the transistors 214A-B.

The gate terminal of the transistors 416, 418 can be coupled to an enable port (e.g., a second enable port) to receive an enable signal (e.g., a second enable signal (EN2)). The second enable port can be different from the enable port (e.g., a first enable port) coupled to the transistors 216, 218. For example, the first enable port can provide enable signal EN1 (e.g., a first enable signal) indicating whether to start the current mirror for the push current and the second enable port can provide enable signal EN2 indicating whether to start the current mirror for the pull current. With the inverter 424 and the conductive type of the transistors 416, 418, the current mirror can start when the EN2 is in a high state (e.g., ‘1’). For example, when the enable signal EN2 is in the high state, the inverter 424 invert the enable signal EN2 to a low state (e.g., low voltage) applied to the gate terminal of the transistors 416, 418. Because the transistors 416, 418 are P-type transistors, in this case, the transistors 416, 418 can allow current to flow through themselves with the low gate voltage. The transistors 416, 418 can receive the inverted version of the enable signal EN2.

The transistor 420 can include a first S/D terminal connected to the commonly connected gate terminals of the transistors 414A-B, a second S/D terminal connected to a source (e.g., current source or voltage source), and a gate terminal connected to the enable signal port via at least inverters 422, 424. The transistor 420 can receive the non-inverted version of the enable signal EN2 by inverting the inverted enable signal EN2 via the inverter 422. In some cases, the gate terminal of the transistor 420 can be connected directly to the enable signal port providing the enable signal EN2. In this case, when the enable signal EN2 is in the high state to start the current mirror (e.g., a relatively high voltage applied to the gate terminal of the transistor 420), the transistor 420 can prevent the gate terminals of the current mirror (e.g., transistors 414A-B) from being connected to the source, allowing shared gate voltage between the transistors 414A-B. If the enable signal EN2 is in the low state to stop/terminate the current mirror (e.g., a relatively low voltage or no voltage applied to the gate terminal of the transistor 420), the transistor 420 can connect the gate terminals of the current mirror to the source, thereby applying a gate voltage to the transistors 414A-B (e.g., P-type transistors), which blocks the current flow through the transistors 414A-B, for example.

The operations of the transistors 414A-B, 416, 418, 420 can be similar to the operation of the transistors 214A-B, 216, 218, 220. For example, to test the driving current (e.g., pull driving current) of the LDO regulator 402, EN2 can be set to the high state and the enable signal EN1 for portion 413A can be set to the low state (e.g., disabling current mirror for the push current). Once in the high state, the current mirror of portion 413B, including transistors 414A-B, can mirror the reference current through the transistor 414A to the driving current through the transistor 414B. The reference current, and in turn the mirrored/driving current, can be increased incrementally or continuously while the output voltage at the output node is monitored. The circuit 400 (or other circuits) can monitor the output voltage to identify whether the output voltage drops. The circuit 400 can monitor the driving current while monitoring the output voltage. The circuit 400 can determine a level of driving current at which the output voltage drops. This level of driving current may represent the maximum driving current of the LDO regulator 402.

In some implementations, the circuit 400 or an external device can use the determined maximum driving current from the testing to compare with a driving current threshold (e.g., pull current threshold) to determine whether the LDO regulator 402 is within the specification. For example, if the maximum driving current is below the threshold, the external device can determine that the LDO regulator 402 is outside or not within the specification. If the maximum driving current is above or at the threshold, the external device can determine that the LDO regulator 402 is within the specification. The maximum driving current may be compared with a predefined driving current range, such that the maximum driving current outside the range is considered not within the specification of the LDO regulator 402 and the maximum driving current inside the range is considered within the specification.

FIG. 5 illustrates an example schematic diagram of a circuit 500 including multiple push-pull LDO regulators 402 of FIG. 4 coupled to a test circuit 502, in accordance with some embodiments. The circuit 500 can include one or more components similar to at least one of but not limited to circuits 200, 300, 400 described in conjunction with FIGS. 2-4. The circuit 500 can include additional or alternative components to circuits 200, 300, 400. The circuit 500 can include one or more features or perform one or more operations similar to or different from at least one of but not limited to circuits 200, 300, 400, described in conjunction with FIGS. 2-4. For example, the circuit 500 can include a plurality of LDO regulators 402 and a test circuit 502. The LDO regulators 402 can be described in conjunction with at least FIG. 4. Each of the LDO regulators 402 can be configured to provide an output voltage at an output node, for instance, for accessing at least a portion of the memory array 102 of the memory circuit 100. The test circuit 502 can be configured to individually test the LDO regulators 402, the driving current of individual LDO regulators 402, or the characteristics of the circuit 500, for example. The test circuit 502 can include one or more components similar to (or different from) at least one of the test circuits 212, 302, 412, as described in conjunction with FIGS. 2-4, among others. In this case, the test circuit 502 can be configured to test the pull current (e.g., pull driving current) and the push current (e.g., push driving current) from the LDO regulators 402. It should be noted that the circuit 500 and/or the components of the circuit 500 can include additional or alternative components, not limited to those discussed herein.

The circuit 500 can include the plurality of LDO regulators 402 coupled to the test circuit 502. Each LDO regulator 402 can provide an output voltage at a respective output node, e.g., LDO1-6 provide V1-6, respectively, for accessing respective portions of the memory array 102. The test circuit 502 can include portions 503A-B. The portion 503A can include components corresponding to at least the test circuit 302 of FIG. 3 for testing the push current of the plurality of LDO regulators 402. The features or operations of portion 503A of the test circuit 502 can be described in conjunction with at least the test circuit 302 of FIG. 3. The portion 503B can include components similar to at least the portion 413B of the test circuit 412 of FIG. 4. The test circuit 502 can share the test pin with other test modes 528, such as other test circuits. In various arrangements, the reference current can be utilized for portion 503A, portion 503B, and for other test modes 528 independent of each other, for instance, to independently test push current (associated with portion 503A), pull current (associated with portion 503B), or the current to the other test modes 528.

The test circuit 502 can include two current mirrors. The first current mirror for the push current can include the transistors 304A-D (e.g., the current mirror for portion 503A) and the second current mirror for the pull current can include the transistors 504A-D (e.g., the current mirror for portion 503B). The second current mirror can perform operations similar to the first current mirror, e.g., mirroring the reference current as the driving current. As shown, the transistors 504A-D, 506, 508A-F, 512 associated with the portion 503B can have a different conductive type compared to the transistors 304A-D, 306, 308A-F, 312 associated with the portion 503A. The connections between the transistors 504A-D, 506, 508A-F, 512 can be described in conjunction with at least one of but not limited to FIGS. 2-4. The transistor 512 can operate similar to the transistor 420, e.g., connect the gate terminals of the transistors 504A-D to the source to disable current mirroring and disconnect the gate terminals of the transistors 504A-D from the source to allow current mirroring via the shared gate voltage between the transistors 504A-D.

To test the pull current of the LDO regulators 402, the enable signal (e.g., SINK_MEAS_EN) of portion 503B can be set to the high state. The inverted version of the enable signal can be applied to at least the gate terminal of the transistor 506 (e.g., P-type transistor) to allow current flow and as input to the logic gates 510A-F (e.g., sometimes referred to as logic gate(s) 510). The logic gates 510 can be ‘OR’ gates, which can output ‘0’ when the inputs are ‘0’ and output ‘1’ when at least one of the inputs is ‘1’. When the enable signal is ‘1’, the input to the logic gate 510 is ‘0’ (after the inversion by the inverter 514). The circuit 500 or the external device can configure the second input of each logic gate 510 to test individual LDO regulators 402. The output of the logic gates 510 can be connected to the gate terminals of the LDO regulators 402, respectively. The outputs from individual logic gates 510 can correspond to the gate voltage applied at the gate terminals of the respective transistors 508A-F (e.g., sometimes referred to as transistor(s) 508).

The second input for the logic gates 510 can be set to a high state by default to prevent current flow through the transistors 508 (e.g., P-type transistors). With the enable signal set to the high state (e.g., ‘1’), thereby the first input of the logic gates 510 is ‘0’, individual LDO regulators 402 can be tested by setting the second input of the corresponding logic gate 510 (associated with the LDO regulator 402 to test) to a low state (e.g., ‘0’). For example, to test the (pull) driving current of LDO1, the second input of the logic gate 510A can be set to ‘0’. To test the driving current of LDO2, the second input of the logic gate 510B can be set to ‘0’. To test the driving current of LDO3, the second input of the logic gate 510C can be set to ‘0’, etc. When the relatively low voltage (e.g., ‘0’) is applied to the gate terminal of the transistor 508, the transistor 508 can allow the driving current or the mirrored current to flow through itself.

The reference current through the transistor 504A can be mirrored to one of the transistors 504B-D similar to mirroring the current mirror through the transistor 304A to one of the transistors 304B-D. The mirrored current can be proportional to the size of the transistors 304B-D. For example, the bigger the transistors 304B-D relative to the transistor 304A, the greater the mirrored current, e.g., the mirrored current can be multiplied by the ratio between the sizes of one of the transistors 304B-D and the transistor 304A. The size of the transistors 304B-D (and/or the transistor 304A) can be implemented based on the expected driving range for each LDO regulator 402.

In operation, the circuit 500 (e.g., test circuit 502) can incrementally or continuously increase the reference current while monitoring the output voltage at the output node of the LDO regulator 402 being tested. In response to identifying that the output voltage drops, the circuit 500 (e.g., test circuit 502) can determine the maximum driving current that causes the output voltage drop. The maximum driving current of each LDO regulator 402 can be compared to a respective threshold or range to determine whether the LDO regulator 402 is within the specification. In some implementations, the LDO regulator 402 can be within the specification if the push and pull driving currents are within the predefined range or is at or above the respective thresholds. Otherwise, the LDO regulator 402 may be considered as outside the specification. It should be noted that the circuit 500 can include additional or alternative components, features, or operations not limited to those discussed herein.

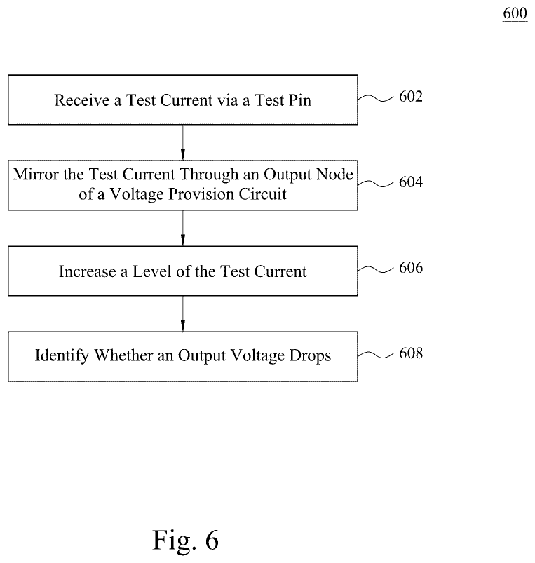

FIG. 6 illustrates a flow chart of an example method 600 for operating the test circuit (e.g., at least one of the test circuits 212, 302, 412, 502) of at least one of FIGS. 1-5, in accordance with various embodiments of the present disclosure. The operations of the method 600 may be performed by the components described hereinabove, e.g., at least one of but not limited to FIGS. 1-5, and thus, some of the reference numerals used above may be re-used the following discussion of the method 600. Further, it is understood that the method 600 has been simplified, and thus, additional operations may be provided before, during, and after the method 600 of FIG. 6, and that some other operations may only be briefly described herein. It should also be noted that alternative operations may be provided as part of the method 600 of FIG. 6.

The method 600 starts with operation 602 of receiving a test current (e.g., reference current) via a test pin. The test pin can supply the test current for mirroring as a driving current. The method 600 proceeds to operation 604 of mirroring the test current as the driving current through an output node of a voltage provision circuit (e.g., LDO regulator 202, 402). The voltage provision circuit can be configured to provide an output voltage at the output node, such as for accessing the memory array (e.g., 102) or a non-volatile memory device. The voltage provision circuit can include a low dropout voltage circuit (e.g., LDO voltage circuit or a LDO regulator 202, 402).

For example, the test pin can supply the test current through a first transistor (e.g., 214A) having a first S/D terminal coupled to the test pin configured to receive the test current and a second S/D terminal coupled to ground. The first transistor can have a gate terminal coupled to a gate terminal of a second transistor (e.g., 214B). The second transistor can have a first S/D terminal coupled to the output node for receiving the mirrored or driving current and a second S/D terminal coupled to ground. The driving current mirroring the test current can flow through the second transistor. For instance, the driving current can flow or traverse from the voltage provision circuit, through the output node, and through the second transistor. By sharing the same gate voltage between the first and second transistors, the same current density can be produced between the transistors, where the second transistor can pull a proportional amount of current according to the transistor size (e.g., the ratio between a second size of the second transistor and a first size of the first transistor). The current mirror including the first and second transistors can be a part of a test circuit (e.g., 212, 302, 412, 502). The test circuit may simulate a load for the voltage provision circuit.

The test circuit can include other components in addition to the first and second transistors. For example, the test circuit can include a third transistor (e.g., 216) having a first S/D terminal and a second S/D terminal connected to the test pin and the first S/D terminal of the first transistor, respectively. The test circuit can include a fourth transistor (e.g., 218) having a first S/D terminal and a second S/D terminal connected to the output node and the first source/drain terminal of the second transistor, respectively. The third transistor and the fourth transistor can have their gate terminals configured to receive an enable signal indicating whether to test the driving current. Depending on the conductive type of the transistors, a high enable signal or a low enable signal may be used to start testing the driving current. For an N-type (e.g., a first conductive type) transistor, the high enable signal can be used to start the driving current, such as described in conjunction with at least FIG. 2, for example.

In some implementations, the test circuit can include a fifth transistor (e.g., 220) having a gate terminal configured to receive a logically inverted version of the enable signal, such as via an inverter (e.g., 222), a first source/drain terminal commonly connected to gate terminals of the first and second transistors, and a second source/drain terminal connected to ground. The fifth transistor can couple the gate terminals of the first and second transistors to ground when the enable signal is in the low state. The fifth transistor can disconnect the gate terminals of the first and second transistors from ground when the enable signal is in the high state, to start mirroring the test current to the driving current.

The mirrored current (e.g., the driving current) can be proportional to the test current according to the size of the first and second transistors. For a relatively greater driving current, the second transistor having a second size can be larger than the first transistor having a first size. In contrast, for the mirrored current to be relatively smaller than the test current, the second size of the second transistor can be smaller than the first size of the first transistor.

The method 600 continues to operation 606 of increasing the level of the test current. When increasing the test current, the driving current can be increased proportionally depending on the second size of the second transistor relative to the first size of the first transistor. While increasing the level of the test current, the method 600 continues to operation 608 of identifying whether an output voltage drops. If the circuit (e.g., 200, 300, 400, 500) or the test circuit identifies or detects the drop in the output voltage, the test circuit can determine the level of the driving current that causes the output voltage drop to be the maximum driving current of the voltage provision circuit.

In some configurations, there may be multiple voltage provision circuits to be tested. For example, the voltage provision circuit may be a first voltage provision circuit (e.g., LDO1). The circuit (e.g., 300, 500) may include a second voltage provision circuit (e.g., LDO2) configured to provide a second output voltage (e.g., V2) at a second output node. The second output voltage may be different from a first output voltage (e.g., V1) provided by the first voltage provision circuit. In this case, the current mirror of the test circuit (e.g., 302, 502) can include a third transistor (e.g., 304C) having a first S/D terminal coupled to the second output node and a second S/D terminal coupled to ground. The gate terminal of the third transistor can be commonly connected with the gate terminals of the first and second transistors (e.g., 304A, 304B). In some implementations, the first transistor has a first size, the second transistor has a second size, and the third transistor has a third size, where the second and third sizes may be different from each other and each can be larger than the first size. The sizes of the transistors can be based on the expected driving range of the transistors.

To test the first voltage provision circuit and the second voltage provision circuit independently, the test circuit (e.g., 302, 502) can include a fourth transistor (e.g., 306) having a first source/drain terminal and a second source/drain terminal connected to the test pin and the first source/drain terminal of the first transistor, respectively. The test circuit can include a fifth transistor having a first source/drain terminal and a second source/drain terminal connected to the first output node (of the first voltage provision circuit) and the first source/drain terminal of the second transistor, respectively. The test circuit can include a sixth transistor having a first source/drain terminal and a second source/drain terminal connected to the second output node (of the second voltage provision circuit) and the first source/drain terminal of the third transistor (e.g., 304C), respectively.

The test circuit can include logic gates (e.g., 310) configured to control the flow of current through the fifth and sixth transistors based on which of the first and second voltage provision circuits to test. For example, the test circuit can include a first logic gate (e.g., 310A) having a first input connected to a gate terminal of the fourth transistor (e.g., to receive the enable signal) and an output connected to a gate terminal of the fifth transistor. A second input of the first logic gate can be received from an external device to control whether to perform current mirroring for the driving current of the first voltage provision circuit. The test circuit can include a second logic gate (e.g., 310B) having a first input connected to the gate terminal of the fourth transistor and an output connected to a gate terminal of the sixth transistor. A second input of the second logic gate can be received from the external device to control whether to perform the current mirroring for the driving current of the second voltage provision circuit.

The gate terminal of the fourth transistor, the first input of the first logic gate, and the first input of the second logic gate are configured to receive the enable signal indicating whether to test the driving current of the respective voltage provision circuit. For example, to test the driving current of the first provisional circuit, the enable signal and the second input of the first logic gate can be set to ‘1’, thereby allowing current mirroring through the second transistor. In another example, to test the driving current of the second provisional circuit, the enable signal and the second input of the second logic gate can be set to ‘1’, thereby allowing current mirroring through the third transistor. Each of the voltage provision circuits can be tested in a similar manner, such as by increasing the test current to proportionally increase the driving current from the respective voltage provision circuit, and determining the level of the driving current when the output voltage of the respective voltage provision circuit drops.

In some implementations, the test circuit (e.g., 412, 502) can include multiple current mirrors, e.g., a first current mirror (e.g., associated with portion 413A, 503A) and a second current mirror (e.g., associated with portion 413B, 503B) for testing the push and pull currents of the voltage provision circuit(s). In such cases, for example, the first current mirror can include the first and second transistors (e.g., 214A-B) and the second current mirror can include third and fourth transistors (e.g., 414A-B). The third transistor can have a first S/D terminal coupled to the test pin configured to receive the test current and a second S/D terminal coupled to a source. The fourth transistor can have a first S/D terminal coupled to the output node of the voltage provision circuit and a second S/D terminal coupled to the source. In this case, for testing different direction of the driving current, the first and second transistors can have a first conductive type (e.g., N-type) and the third and fourth transistors can have a second conductive type (e.g., P-type) different from the first conductive type, for example. The driving current through the fourth transistor can be test independently from the driving current through the second transistor. The test can be performed independently between the first current mirror and the second current mirror by receiving different enable signals between the two current mirrors, e.g., a first enable signal (e.g., EN1) used for the first current mirror and a second enable signal (e.g., EN2) used for the second current mirror. It should be noted that current can be transferred to or drawn from the test pin depending on whether to test the driving current or the sinking current. For instance, to test the driving current through the N-type current mirror (e.g., circuit or portion 413A), current can be transferred to the test pin, and to test the sinking current, current can be drawn from the test pin. The driving current and the sinking current can be tested independent of each other.

In one aspect of the present disclosure, a circuit is disclosed. The circuit includes a first voltage provision circuit configured to provide a first output voltage at a first output node; and a test circuit coupled to the first voltage provision circuit and configured to test a driving current flowing through the first output node; wherein the test circuit comprises a current mirror that comprises: a first transistor having a first source/drain terminal coupled to a test pin configured to receive a test current; and a second transistor having a first source/drain terminal coupled to the first output node.

In another aspect of the present disclosure, a circuit is disclosed. The circuit includes a memory array; a voltage provision circuit configured to provide an output voltage at an output node, wherein the output voltage is configured for accessing the memory array; and a test circuit coupled to the voltage provision circuit and configured to test a driving current flowing through the output node to the memory array; wherein the test circuit comprises a current mirror configured to mirror a test current as the driving current.

In yet another aspect of the present disclosure, a method for operating a circuit is disclosed. The method includes receiving a test current and mirroring the test current as a driving current flowing through an output node of a voltage provision circuit, wherein the voltage provision circuit is configured to provide an output voltage at the output node. The method includes increasing a level of the test current. With the increasing level of the test current, the method includes identifying whether the output voltage drops to determine a level of the driving current.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit, comprising:
a first voltage provision circuit configured to provide a first output voltage at a first output node; and
a test circuit coupled to the first voltage provision circuit and configured to test a driving current flowing through the first output node;
wherein the test circuit comprises a current mirror that comprises:
a first transistor having a first source/drain terminal coupled to a test pin configured to receive a test current; and
a second transistor having a first source/drain terminal coupled to the first output node.

2. The circuit of claim 1, wherein the current mirror comprises:
a third transistor having a first source/drain terminal and a second source/drain terminal connected to the test pin and the first source/drain terminal of the first transistor, respectively; and
a fourth transistor having a first source/drain terminal and a second source/drain terminal connected to the first output node and the first source/drain terminal of the second transistor, respectively.

3. The circuit of claim 2, wherein the third transistor and the fourth transistor have their gate terminals configured to receive an enable signal indicating whether to test the driving current.

4. The circuit of claim 3, wherein the current mirror comprises:
a fifth transistor having a gate terminal configured to receive a logically inverted version of the enable signal, a first source/drain terminal commonly connected to gate terminals of the first and second transistors, and a second source/drain terminal connected to ground.

5. The circuit of claim 1, wherein the first transistor has a first size and the second transistor has a second size, and wherein the second size is larger than the first size.

6. The circuit of claim 1, wherein the first output voltage is configured for accessing a non-volatile memory device.

7. The circuit of claim 1, further comprising:
a second voltage provision circuit configured to provide a second output voltage at a second output node;
wherein the second output voltage is different from the first output voltage.

8. The circuit of claim 7, wherein the current mirror comprises:
a third transistor having a first source/drain terminal coupled to the second output node;
wherein the first transistor has a first size, the second transistor has a second size, and the third transistor has a third size, the second and third sizes being different from each other and each larger than the first size.

9. The circuit of claim 8, wherein the current mirror comprises:
a fourth transistor having a first source/drain terminal and a second source/drain terminal connected to the test pin and the first source/drain terminal of the first transistor, respectively;
a fifth transistor having a first source/drain terminal and a second source/drain terminal connected to the first output node and the first source/drain terminal of the second transistor, respectively; and
a sixth transistor having a first source/drain terminal and a second source/drain terminal connected to the second output node and the first source/drain terminal of the third transistor, respectively.

10. The circuit of claim 9, wherein the current mirror comprises:
a first logic gate having a first input connected to a gate terminal of the fourth transistor and an output connected to a gate terminal of the fifth transistor; and
a second logic gate having a first input connected to the gate terminal of the fourth transistor and an output connected to a gate terminal of the sixth transistor.

11. The circuit of claim 10, wherein the gate terminal of the fourth transistor, the first input of the first logic gate, and the first input of the second logic gate are configured to receive an enable signal indicating whether to test the driving current.

12. The circuit of claim 1, wherein the test circuit comprises another current mirror that comprises:
a third transistor having a first source/drain terminal coupled to the test pin configured to receive the test current; and
a fourth transistor having a first source/drain terminal coupled to the first output node;
wherein the first and second transistors have a first conductive type, and the third and fourth transistors have a second conductive type.

13. A circuit, comprising:
a memory array;
a voltage provision circuit configured to provide an output voltage at an output node, wherein the output voltage is configured for accessing the memory array; and
a test circuit coupled to the voltage provision circuit and configured to test a driving current flowing through the output node to the memory array;
wherein the test circuit comprises a current mirror configured to mirror a test current as the driving current.

14. The circuit of claim 13, wherein the current mirror comprises:
a first transistor having a first source/drain terminal coupled to a test pin configured to receive the test current; and
a second transistor having a first source/drain terminal coupled to the output node through which the driving current flows.

15. The circuit of claim 14, wherein to start mirroring the test current, the test circuit is configured to:
receive an enable signal indicating whether to test the driving current via gate terminals of a third transistor and a fourth transistor, wherein the third transistor have a first source/drain terminal coupled to the test pin and a second source/drain terminal coupled to the first transistor, and wherein the fourth transistor have a first source/drain terminal coupled to the output node and a second source/drain terminal connected to the first source/drain terminal of the second transistor.

16. The circuit of claim 13, wherein the voltage provision circuit is one of a plurality of voltage provision circuits configured to provide a plurality of output voltages at respective output nodes for accessing the memory array, and wherein the test circuit is coupled to the plurality of voltage provision circuits and configured to test a plurality of driving currents flowing through the respective output nodes to the memory array.

17. The circuit of claim 13, wherein the test circuit further comprises a second current mirror configured to mirror the test current as the driving current, wherein the current mirror and the second current mirror comprises a first plurality of transistors and a second plurality of transistors, respectively, and wherein the first plurality of transistors have a first conductive type different from a second conductive type of the second plurality of transistors.

18. A method, comprising:
receiving a test current and mirroring the test current as a driving current flowing through an output node of a voltage provision circuit, wherein the voltage provision circuit is configured to provide an output voltage at the output node;
increasing a level of the test current; and
with the increasing level of the test current, identifying whether the output voltage drops to determine a level of the driving current.

19. The method of claim 18, wherein the voltage provision circuit comprises a low dropout voltage circuit.

20. The method of claim 18, wherein the test current is received and mirrored by a test circuit, comprising:
a first transistor having a first source/drain terminal coupled to a test pin configured to receive the test current; and
a second transistor having a first source/drain terminal coupled to the output node and configured to mirror the test current through the output node,
wherein to mirror the test current, the method comprises:
receiving an enable signal indicating whether to test the driving current via gate terminals of a third transistor and a fourth transistor, the third transistor having a first source/drain terminal and a second source/drain terminal connected to the test pin and the first source/drain terminal of the first transistor, respectively, and the fourth transistor having a first source/drain terminal and a second source/drain terminal connected to the output node and the first source/drain terminal of the second transistor, respectively.
